(19) United States
(12) Patent Application Publication
(10) Pub. No.: US 2004/0017725 A1
(43) Pub. Date: Jan. 29, 2004

(54) Automated adaptation of the supply voltage of a light-emitting display according to the desired luminance

(76) Inventors: Celine Mas, Poisat (FR); Eric Benoit, Quaix En Chartreuse (FR); Olivier Scouarnec, Saint Nazaire Les Eymes (FR); Olivier Le Briz, Saint-Gervais (FR)

Correspondence Address: WOLF GREENFIELD & SACKS, PC, FEDERAL RESERVE PLAZA, 600 ATLANTIC AVENUE, BOSTON, MA, 02210-2211, US

(21) Appl. No.: 10/622,416

(22) Filed: Jul. 18, 2003

(30) Foreign Application Priority Data
Jul. 19, 2002 (FR) 02/09227

(51) Int. Cl. G11C 7/00

(52) U.S. Cl. 365/222

(57) ABSTRACT

A method for regulating the biasing voltage of column control circuits of an array screen formed of LEDs distributed in lines and columns, the column control circuits being adapted to turning on at least one LED of a line. The method consists of increasing the biasing voltage when the current flowing through at least one activated LED is smaller than a determined luminance current and of decreasing the biasing voltage when the current flowing through each activated LED is equal to the determined luminance current.

### BACKGROUND OF THE INVENTION

1. Field of the Invention

The present invention relates to light-emitting display array screens formed of an assembly of light-emitting diodes (LEDs). These are, for example, screens formed of organic diodes (“OLED”, for Organic Light-Emitting Display) or polymer diodes (“PLED”, for Polymer Light-Emitting Display). The present invention more specifically relates to the regulation of the supply voltage of the circuits controlling the LEDs of such screens.

2. Discussion of the Related Art

FIG. 1 shows an array screen comprised of n columns C₁ to Cₙ and k lines L₁ to Lₖ enabling addressing of n*k LEDs d, the anodes of which are connected to a column and the cathodes of which are connected to a line.

Line control circuits CL₁ to CLₖ enable respectively biasing lines L₁ to Lₖ. Only a single line is activated at a time, and is grounded. The non-activated lines are biased to a voltage Vₗᵢₙₑ.

Columns control circuits CC₁ to CCₙ enable respective biasing of columns C₁ to Cₙ. The columns addressing the LEDs which are desired to be activated are biased by a current to a voltage V_{col} greater than the threshold voltage of the LEDs of the screen. The columns which are not desired to be activated are grounded.

A LED connected to the activated line and to a column biased to V_{col} is then on and emits light. Voltage Vₗᵢₙₑ is provided to be sufficiently high so that the LEDs connected to the non-activated lines at voltage V_{col} and to the columns are not conductive and do not emit light.

FIG. 2 shows a column control circuit CC and a line control circuit CL respectively addressing a column C and a line L connected to a LED d of the screen. Line control circuit CL comprises a power inverter 1 controlled by a line control signal φ_{L}. Power inverter 1 comprises an NMOS transistor 2 enabling discharge of line L when φ_{L} is high and a PMOS transistor 3 enabling charging line L to bias voltage Vₗᵢₙₑ when φ_{L} is low.

Column control circuit CC comprises a current mirror formed in the present example with two transistors 4, 5 of type PMOS. Transistor 4 forms the reference branch of the mirror and transistor 5 forms the duplication branch. The sources of transistors 4 and 5 are connected to a biasing voltage Vₚₒₗ on the order of 15 V for OLED screens. The gates of transistors 4 and 5 are connected to each other. The drain and the gate of transistor 4 are connected to each other. Transistor 4 is thus diode-assembled, the source-gate voltage (Vsg₄) being equal to the source-drain voltage (Vsd₄). The current running through transistor 4 is set by a current source 6 connected to the drain of transistor 4. Current 6 provides a so-called “luminance” current I₁. The drain of transistor 5 is connected to column C via a column selection circuit formed of a PMOS transistor 7 and of an NMOS transistor 8. The source of PMOS transistor 7 is connected to the drain of transistor 5 and the drain of transistor 7 is connected to column C. The source of transistor 8 is grounded and its drain is connected to column C. A column control signal φ_{C} is connected to the gate of PMOS transistor 7 and to the gate of NMOS transistor 8. When column control signal φ_{C} is high, transistor 8 discharges column C. When it is low, transistor 7 is on and column C charges to reach voltage V_{col}. When line L and column C are activated, line control signal φ_{L} and column control signal φ_{C} are respectively high and low, LED d is on and the current flowing through the diode is equal to luminance current I₁.

However, for column control circuit CC to operate as described previously, it is necessary for voltage Vₚₒₗ to be sufficiently high for the copy of current I₁ to be correct. Biasing voltage Vₚₒₗ is equal to the sum of source-drain voltage Vsd₂ of transistor 2, of voltage V_{d} across LED d, of source-drain voltage Vsd₇ of transistor 7, and of source-drain voltage Vsd₅ of transistor 5.

When the copy of current I₁ is correct, transistor 5 is in saturation state and voltage Vsd₅ is at least equal to source-drain voltage Vsd₄ of transistor 4. A correct copy thus imposes for biasing Vₚₒₗ to be at least equal to the previously-mentioned sum when the current flowing therethrough is equal to luminance current I₁. If biasing voltage Vₚₒₗ is too low, the current flowing through LED d is smaller than current I₁ and the luminance of the diodes is insufficient.

Luminance current I₁ provided by current source 6 may generally vary according to the luminance desired for the screen. When luminance current I₁ increases, source-drain voltage Vsd₄ of diode-assembled transistor 4 increases and voltage V_{d} of light-emitting diode d also increases. As a result, biasing voltage Vₚₒₗ must be sufficiently high for transistor 5 to be in saturation whatever the luminance current.

However, in a concern for electric power saving, biasing voltage Vₚₒₗ is desired to be reduced, which then enables reducing voltage Vₗᵢₙₑ of the line control circuits.

There exist control circuits which have a fixed biasing voltage Vₚₒₗ determined according to the maximum desired luminance current I₁. The disadvantage of such circuits is their strong electric power consumption.

There exist other control circuits for which biasing voltage Vₚₒₗ varies according to the desired luminance current I₁. If current I1 is low, voltage Vₚₒₗ is low, and conversely. However, it is necessary to provide a security margin to take the aging of the LEDs of the screen into account. Indeed, for an equal current in LED d, voltage V_{d} across the diode increases along time. For a same luminance, the necessary minimum biasing voltage Vₚₒₗ thus progressively increases along time. The power savings obtained for these circuits are thus not optimal.

### SUMMARY OF THE INVENTION

An object of the present invention is to provide a column control circuit, biasing voltage Vₚₒₗ of which is as small as possible whatever the aging of the LEDs of the screen.

Another object of the present invention is to provide a control circuit of simple structure.

To achieve these objects, the present invention provides a device for regulating the biasing voltage of column control circuits of an screen array made of LEDs distributed in lines and columns, the column control circuits comprising a current mirror having a reference branch and several duplication branches connected to the biasing voltage, each duplication branch being coupled to a column of the screen, the reference branch being connected at a reference node to a reference current source providing a desired luminance current, said device comprising: first measuring means providing a first signal representative of the voltage of at least one of the columns; second measuring means providing a second signal representative of the voltage of the reference node; and an adjustment circuit receiving the first and second signals and being adapted to increase the biasing voltage when the first signal is lower than the second signal and conversely.

According to an embodiment of such a device, each branch of the current mirror includes a PMOS field effect transistor, having a source connected to the biasing voltage, the gates of each branch being connected together, the drain and the gate of the transistor of the reference branch being connected to the reference current source, the drains of the transistors of the duplication branches being connected to the columns.

According to an embodiment of such a device, first measuring means comprise for each column a diode having an anode connected to the column and having an cathode connected to a first observation current source and to a first input of the adjustment circuit, and wherein the second measuring means comprise a diode having an anode connected to the reference node and a cathode connected to a second observation current source and to a second input of the adjustment circuit.

According to an embodiment of such a device, the cathodes of all the diodes are connected to the first input of the adjustment circuit by a switch, a capacitor being connected between the first input of the adjustment circuit and a fixed voltage node.

According to an embodiment of such a device, the adjustment circuit comprises an error amplifier receiving the first signal on a positive input and receiving the second signal on a negative input, an output of error amplifier being connected to a D.C./D.C. voltage converter outputting the biasing voltage and being adapted to increase the biasing voltage when the first signal is higher than the second signal and conversely.

According to an embodiment of such a device, error amplifier comprises first and second PMOS transistors having their gates respectively connected to positive and negative inputs of the error amplifier, the source of each one of the first and second transistors being connected to the biasing voltage by a current source, the sources of first and second transistors being connected by a resistor, the drains of first and second transistors being connected to a converter providing the error signal, the source and drain of a third PMOS transistor being connected to the source and drain of the first transistor, the gate of the third transistor being connected to a fixed voltage.

The present invention also provides a method for regulating the biasing voltage of column control circuits of an screen array made of LEDs distributed in lines and columns, the column control circuits comprising a current mirror having a reference branch and several duplication branches connected to the biasing voltage, each duplication branch being coupled to a column of the screen, the reference branch being connected at a reference node to a reference current source providing a desired luminance current, comprising the following steps: providing a first signal representative of the voltage of at least one of the columns; providing a second signal representative of the voltage at the reference node; and increasing the biasing voltage when the first signal is higher than the second signal and conversely.

According to an embodiment of such a device, the first signal is an image of the maximum voltage of the activated LEDs.

The foregoing objects, features and advantages of the present invention, will be discussed in detail in the following non-limiting description of specific embodiments in connection with the accompanying drawings.

### BRIEF DESCRIPTION OF THE DRAWINGS

FIG. 1, previously described, shows a light-emitting array display;

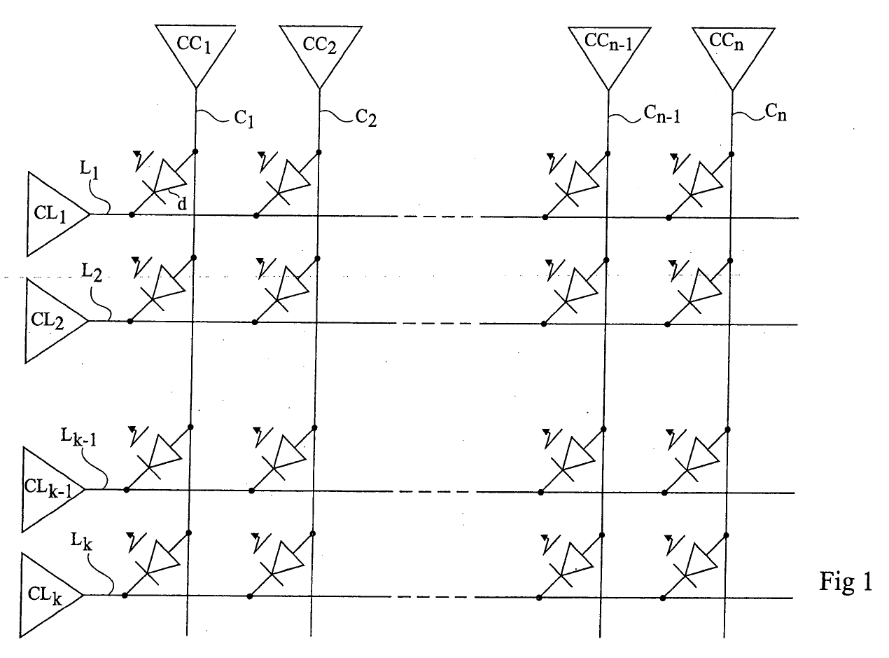

FIG. 2, previously described, shows a column control circuit and a line control circuit addressing a LED of a screen;

FIG. 3 illustrates an exemplary embodiment of the regulation device according to the present invention;

FIG. 4 illustrates a more detailed embodiment of the device of FIG. 3;

FIG. 5 illustrates another exemplary embodiment of the regulation device according to the present invention; and

FIG. 6 illustrates an embodiment of one element of the device of FIG. 4.

### DETAILED DESCRIPTION

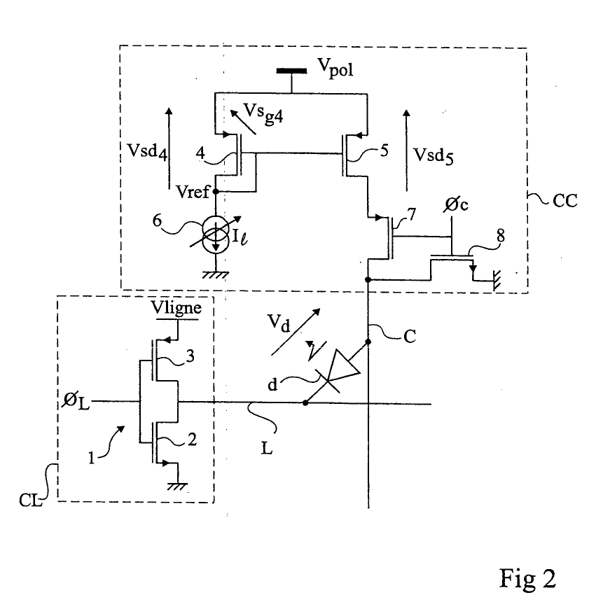

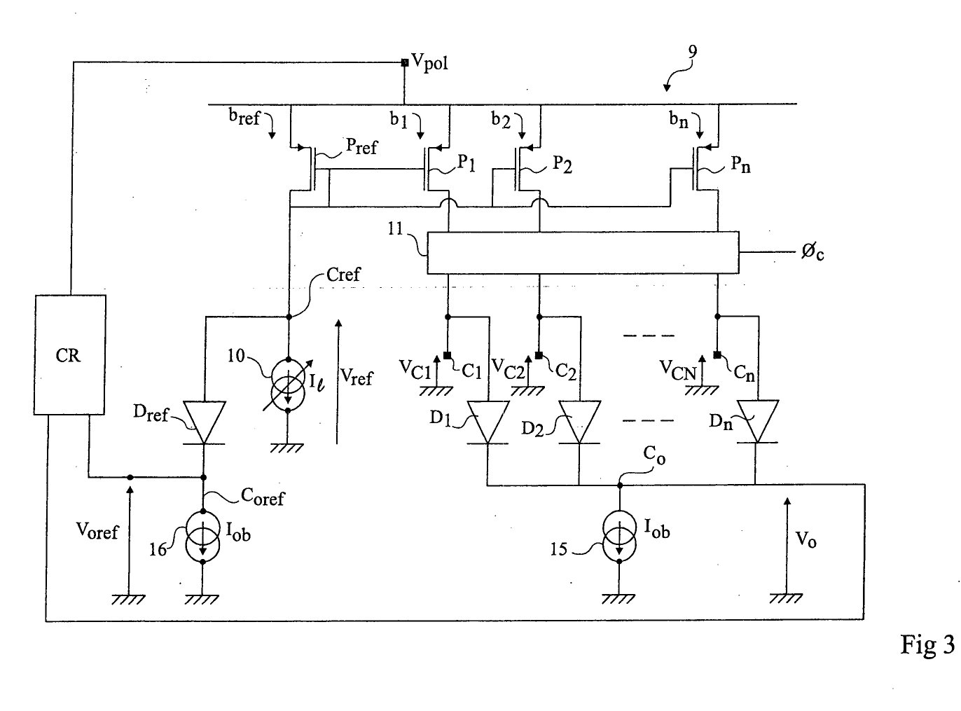

FIG. 3 is a diagram of an embodiment of column control circuits and of the device for regulating biasing voltage Vₚₒₗ according to the present invention. The column control circuits comprise a current mirror 9 formed of a reference branch b_{ref} and of n duplication branches b₁ to bₙ. Each branch is formed of a PMOS transistor, P_{ref} for the reference branch and P₁ to Pₙ for branches b₁ to bₙ. The sources of the transistors of each of the branches are connected to biasing voltage Vₚₒₗ and the gates are connected to one another. The drain and the gate of transistor P_{ref} of the reference branch are connected to a reference current source 10 at a node C_{ref}. Reference current source 10 provides a luminance current I₁. The drain of each transistor Pᵢ, i ranging between 1 and n, is connected to a column Cᵢ of the screen via a column selection circuit such as described in relation with FIG. 2. All the column selection circuits are represented by a selection device 11 controlled by a column signal φ_{C}.

Each column C₁ to Cₙ is connected to the anode of a diode, respectively D₁ to Dₙ. The cathodes of diodes D₁ to Dₙ are connected to a current source 15 at a node Cₒ. Current source 15 provides a so-called observation current I_{ob} selected to be small as compared to the minimum luminance current. Further, connection node C_{ref} is connected to the anode of a diode D_{ref} identical to diodes D₁ to Dₙ, the cathode of diode D_{ref} is connected at a node C_{oref} to a current source 16 providing a current equal to observation current I_{ob}. Nodes C_{ref} and Cₒ are connected to two inputs of an adjustment circuit CR which provides biasing voltage Vₚₒₗ.

As indicated previously, the LEDs may, even when run through by a same current, exhibit across their terminals different voltage drops. Especially, this voltage drop tends to increase when the LEDs age. The present invention aims at adjusting voltage Vₚₒₗ to take these voltage variations into account and ensure that the chosen luminance current I₁ flows through all the selected columns, Vₚₒₗ remaining as small as possible.

Diodes D₁ to Dₙ corresponding to the selected columns tend to be conductive. However, the diode connected to the column having the highest voltage imposes voltage Vₒ on the cathodes of diodes D₁ to Dₙ. The other diodes are thus not conductive since the voltage thereacross is smaller than their threshold voltage. Voltage Vₒ is the image of the voltage on the column having the highest voltage shifted by diode threshold voltage. Similarly, voltage V_{oref} at connection node C_{oref} is the image of voltage V_{ref} shifted by a diode threshold voltage.

When voltage Vₒ is greater than voltage V_{oref}, this means that the current in at least one of the screen columns is smaller than the chosen luminance current I₁. Adjustment circuit CR then raises biasing voltage Vₚₒₗ until voltages Vₒ and V_{oref} are equal.

Conversely, when voltage Vₒ is smaller than V_{oref}, this implies that the chosen luminance current I₁ does flow through all the selected columns but that voltage Vₚₒₗ is too high, which results in a power overconsumption. To make electric power savings, the adjustment circuit decreases biasing voltage Vₚₒₗ down to the minimum voltage Vₚₒₗ ensuring a flow of luminance current I₁ in all the selected columns.

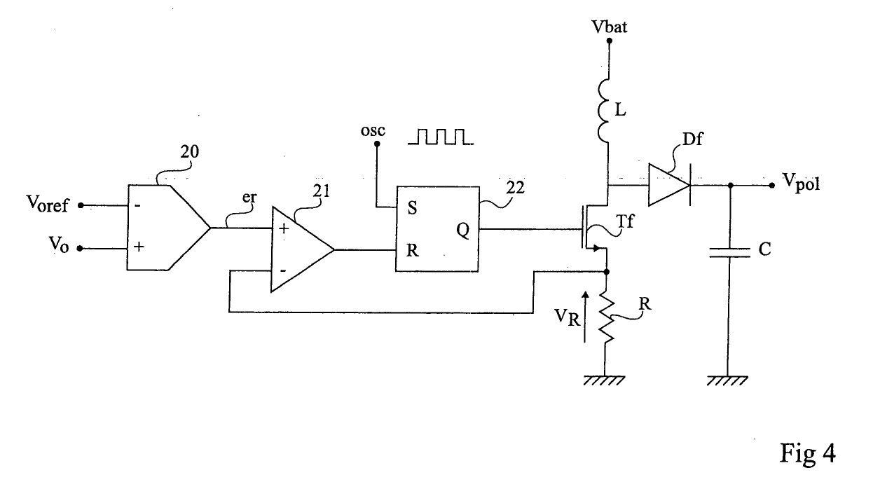

FIG. 4 is a diagram of the circuit for adjusting biasing voltage Vₚₒₗ according to the difference between voltages Vₒ and V_{oref}.

The adjustment circuit comprises an error amplifier 20, an operational amplifier 21, and an RS flip-flop 22 operating with a low supply voltage, for example, 3.3 V. Error amplifier 20 receives on a positive input voltage Vₒ and on a negative input voltage V_{oref}. In the case when the levels of voltages Vₒ and V_{oref} are very high for error amplifier 20, a voltage converter providing voltages proportional to voltages Vₒ and V_{oref} over a lower voltage range may be provided.

Error amplifier 20 amplifies the difference between Vₒ and V_{oref} and provides an error signal er which varies for example between 1 and 2 V. When voltages Vₒ and V_{oref} are equal, the error signal is for example 1.5 V. The higher voltage Vₒ with respect to V_{oref}, the higher signal er, and conversely. Signal er is applied to the positive input of differential amplifier 21. The output of differential amplifier 21 is connected to reset terminal R of RS flip-flop 22. The output of an oscillator osc is connected to set terminal S of RS flip-flop 22. Terminal Q is at a high logic level (for example, 3.3 volts) when set terminal S is high and is at a low logic level (for example, 0 V) when reset terminal R is high. When both set terminal S and reset terminal R are low, output Q keeps the last positioned level.

The output of RS flip-flop 22 is connected to the gate of an NMOS transistor Tf. A resistor R is connected between the source of transistor Tf and the ground. A coil L is connected between the drain of transistor Tf and the supply terminal at a voltage V_{bat}, for example, at 3.3 V. The anode of a diode Df is connected to the drain of transistor Tf and its cathode is connected to a first electrode of a capacitor C. The second electrode of capacitor C is grounded. The first electrode of capacitor C provides voltage Vₚₒₗ. The source of transistor Tf is connected to the negative input of differential amplifier 21.

On a rising edge of the signal of oscillator osc, output Q of RS flip-flop 22 switches high. Transistor Tf turns on and the voltage across coil L rapidly switches from 0 to V_{bat}. Voltage VR across resistor R and the current through coil L are initially zero. The current in coil L progressively increases, and voltage VR thus also increases. When voltage VR reaches signal er of differential amplifier 20, amplifier 21 switches high. Output Q of RS flip-flop 22 switches low and transistor Tf turns off. The voltage on the drain of transistor Tf abruptly increases. Diode Df turns on and capacitor C charges. The charge current is all the higher as the current flowing through coil L is high at the time when transistor Tf turns off.

At the next rising edge of oscillator osc, output Q of RS flip-flop 22 switches high again and a cycle identical to that previously described starts again.

When voltage Vₒ is greater than voltage V_{oref}, signal er is relatively high. Accordingly, transistor Tf remains on longer and the current flowing through coil L at the turn-off time of transistor Tf is significant. Capacitor C charges and voltage Vₚₒₗ increases. Conversely, when voltage Vₒ is smaller than voltage V_{oref}, voltage Vₚₒₗ decreases.

Biasing voltage Vₚₒₗ is thus adjusted according to the time variations of the voltage across the LEDs of the screen.

An advantage of the regulation device according to the present invention is that the biasing voltage is always minimum, which enables making power savings.

Another advantage of such a device is that its design is very simple.

Of course, the present invention is likely to have various alterations, modifications, and improvements which will readily occur to those skilled in the art. In particular, other devices for evaluating the current flowing through the LEDs of the screen, as well as other devices for adjusting biasing voltage Vₚₒₗ according to the differences between the desired luminance current and the smallest current flowing through the LEDs of the screen, may be provided. Other D.C./D.C. voltage converters capable of providing a high biasing voltage Vₚₒₗ when error signal er is high and conversely may especially be used. Further, those skilled in the art will know how to make a current mirror different from that described, by using, for example, two transistors per branch.

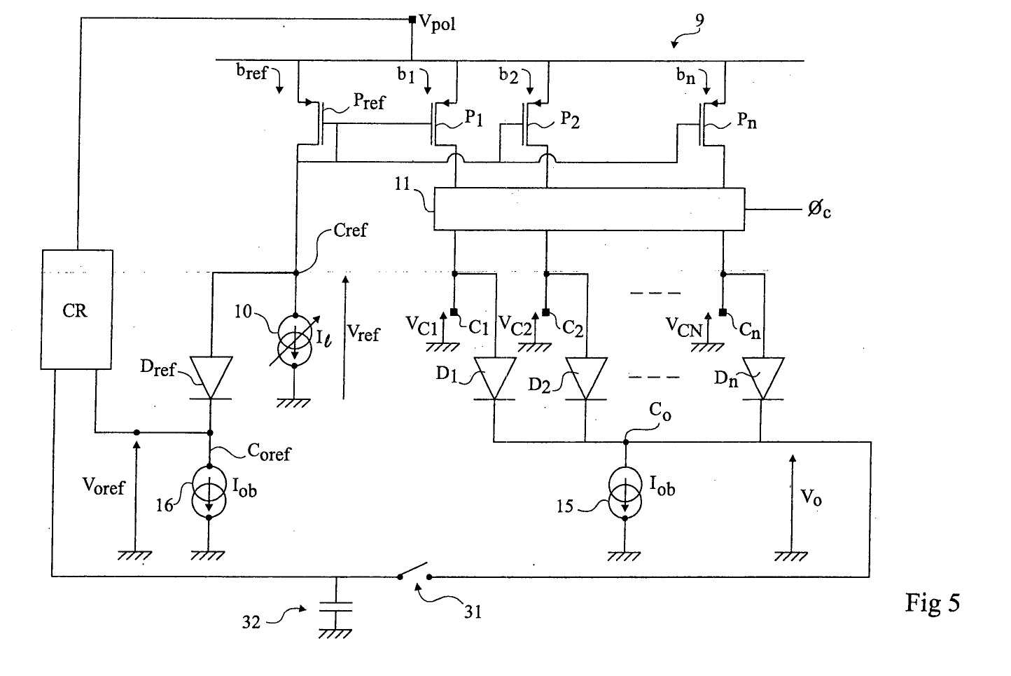

FIG. 5 illustrates column control circuits similar to those of FIG. 3, and a modified embodiment of the device for regulating biasing voltage Vₚₒₗ which solves the following problem. When a screen line is “black”, meaning that no LED of the selected line is conductive, the voltage Vₒ at node Cₒ of the regulation circuit of FIG. 3 decreases because none of the diodes D₁ to Dₙ is on. When voltage Vₒ decreases, the adjustment circuit CR decreases biasing voltage Vₚₒₗ. When a large number of consecutive screen lines are black, the biasing voltage Vₚₒₗ can strongly decrease. The conductive LEDs of bright lines may receive a current lower than the luminance current. The global luminance of the screen decreases.

In this modified embodiment, the device for regulating the biasing voltage Vₚₒₗ is similar to the one of FIG. 3, except that the node Cₒ is linked to the adjustment circuit CR by a switch 31. Besides, a capacitor 32 is connected between the input of adjustment circuit CR and ground. Switch 31 is controlled so as to be non conductive when a screen line is black, i.e. when no LED of the selected line is conductive. Capacitor 32 holds the value of the voltage V_{O} corresponding to the last non-black line. The switch control device, not shown, analyzes the column signal φ_{c} to detect if at least one column is selected, meaning that at least one diode is conductive. Moreover, according to a more sophisticated embodiment, the switch control device analyzes the control signals of the line control circuits in such a way that switch 31 is turned on once the voltages of selected columns have changed from their precharge voltages to their operating voltages corresponding to the voltages induced by each one of the conductive LEDs.

An advantage of such a regulation device is that it is possible to adjust the biasing voltage Vₚₒₗ according to the features of the LEDs of the screen whatever the number of consecutive black screen lines is.

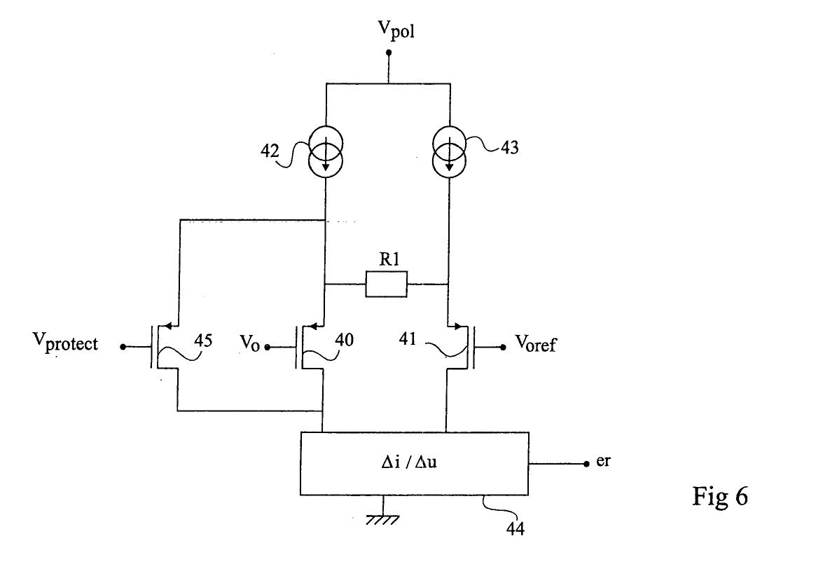

FIG. 6 is a diagram of an embodiment of the error amplifier 20 of the adjustment circuit CR of FIG. 4 which solves the following problem. When the screen or the column or line control circuits include manufacture defects, or an aging defect, corresponding to a cut between the LED and a column or a line, the voltage Vₒ can be very close to the biasing voltage Vₚₒₗ. Such a defect leads not only to a drastic increase of the biasing voltage Vₚₒₗ, but also to overvoltages likely to damage the adjustment circuit CR. In case of an aging defect, it can be interesting to detect the defect in order to avoid damaging the rest of the circuit and to avoid increasing the power consumption to produce a high voltage Vₚₒₗ. The detection of a manufacture defect enables the detection of failing circuits before commercialization.

The error amplifier represented in FIG. 6 includes two PMOS transistors 40 and 41 the gates of which receive voltages Vₒ and V_{oref} respectively from the regulation device represented in FIG. 3. Two identical current sources 42 and 43 are connected between the biasing voltage source Vₚₒₗ and the sources of transistors 40 and 41. A resistor R1 is connected between the sources of transistors 40 and 41. The drains of transistors 40 and 41 are linked to a conversion device 44, which provides the error signal er. A PMOS transistor 45 is connected in parallel with the transistor 40. The source of transistor 45 is connected to the source of transistor 40 and the drain of transistor 45 is connected to the drain of transistor 40. The gate of transistor 45 receives a “protection” voltage V_{protect} which is produced by a device not shown. The protection voltage V_{protect} corresponds to the maximum voltage Vₒ corresponding to a correct operation of the screen and of the column and line control circuits.

During normal operation, with no defect in the circuit, the voltage Vₒ is lower than protection voltage V_{protect}. Transistors 40, 41 and 45 conduct a current equal to the current provided by current sources 42 and 43, their gate-source voltages being substantially equal to the threshold voltage of a PMOS transistor. Thus, when voltage Vₒ is lower than voltage V_{protect}, transistor 45 is non conductive. Similarly, when voltages Vₒ and V_{oref} are different, voltages on the sources of transistors 40 and 41 are different. The current flowing through resistor R1 increases when the difference between voltages Vₒ and V_{oref} increases. Conversion device 44 analyzes the current differences in transistors 40 and 41 and provides an error signal er which is high when the current in transistor 40 is low compared to the current in transistor 41 and conversely.

When the circuit has a defect, voltage Vₒ can be very close to biasing voltage Vₚₒₗ. When voltage Vₒ is higher than the protection voltage V_{protect}, transistor 45 is turned on and transistor 40 off. The biasing voltage Vₚₒₗ is then maximum. The maximum value of voltage Vₚₒₗ depends upon the choice of voltage V_{protect} and voltage V_{oref} which varies according to the desired luminance current. Thanks to transistor 45, it is sure that biasing voltage Vₚₒₗ will not go over a maximum given value, and overvoltages which could damage adjustment circuit CR are suppressed.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A device for regulating the biasing voltage (Vₚₒₗ) of column control circuits of an screen array made of LEDs distributed in lines and columns, the column control circuits comprising a current mirror having a reference branch (bref) and several duplication branches (b1 to bn) connected to the biasing voltage (Vpol), each duplication branch (bi) being coupled to a column (Ci) of the screen, the reference branch being connected at a reference node to a reference current source (10) providing a desired luminance current (I1), said device comprising:
first measuring means providing a first signal representative of the voltage of at least one of the columns;
second measuring means providing a second signal representative of the voltage of the reference node; and
an adjustment circuit receiving the first and second signals and being adapted to increase the biasing voltage when the first signal is lower than the second signal and conversely.

2. The device of claim 1, wherein each branch (bi) of the current mirror includes a PMOS field effect transistor (Pi), having a source connected to the biasing voltage, the gates of each branch being connected together, the drain and the gate of the transistor of the reference branch being connected to the reference current source (10), the drains of the transistors of the duplication branches being connected to the columns (C1 to Cn).

3. The device of claim 1, wherein said first measuring means comprise for each column (Ci) a diode (Di) having an anode connected to the column (Ci) and having an cathode connected to a first observation current source (15) and to a first input of the adjustment circuit, and wherein the second measuring means comprise a diode (Dref) having an anode connected to the reference node and a cathode connected to a second observation current source (16) and to a second input of the adjustment circuit.

4. The device of claim 3, wherein the cathodes of all the diodes (Di) are connected to the first input of the adjustment circuit by a switch (31), a capacitor (32) being connected between the first input of the adjustment circuit (CR) and a fixed voltage node.

5. The device of claim 3, wherein the adjustment circuit comprises an error amplifier (20) receiving the first signal on a positive input and receiving the second signal on a negative input, an output of error amplifier (ER) being connected to a D.C./D.C. voltage converter outputting the biasing voltage (Vpol) and being adapted to increase the biasing voltage (Vpol) when the first signal is higher than the second signal and conversely.

6. The device of claim 5, wherein error amplifier (20) comprises first and second PMOS transistors (40, 41) having their gates respectively connected to positive and negative inputs of the error amplifier, the source of each one of the first and second transistors being connected to the biasing voltage (Vpol) by a current source (42, 43), the sources of first and second transistors being connected by a resistor (R1), the drains of first and second transistors being connected to a converter (44) providing the error signal, the source and drain of a third PMOS transistor (45) being connected to the source and drain of the first transistor (40), the gate of the third transistor being connected to a fixed voltage (Vprotect)).

7. A method for regulating the biasing voltage (Vpol) of column control circuits of an screen array made of LEDs distributed in lines and columns, the column control circuits comprising a current mirror having a reference branch (bref) and several duplication branches (b1 to bn) connected to the biasing voltage (Vpol), each duplication branch (bi) being coupled to a column (Ci) of the screen, the reference branch being connected at a reference node to a reference current source (10) providing a desired luminance current (I1), comprising the following steps:
providing a first signal representative of the voltage of at least one of the columns;
providing a second signal representative of the voltage at the reference node; and
increasing the biasing voltage when the first signal is higher than the second signal and conversely.

8. The method of claim 7, wherein the first signal is an image of the maximum voltage of the activated LEDs.
